(19) United States
(12) Patent Application Publication
(10) Pub. No.: US 2008/0197931 A1
(43) Pub. Date: Aug. 21, 2008

(54) OSCILLATOR

(75) Inventor: Yosuke Ueno, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: Sony Corporation, Tokyo (JP)

(21) Appl. No.: 12/031,796

(22) Filed: Feb. 15, 2008

(30) Foreign Application Priority Data
Feb. 16, 2007 (JP) 2007-036425

(51) Int. Cl. H03K 3/03

(52) U.S. Cl. 331/57

(57) ABSTRACT

The present invention provides an oscillation circuit including: a plurality of multi-stage inverter rings each having an odd number of inverters connected to each other in cascade to form a ring through the same odd number of nodes on the ring; an inverter group for connecting each one of the nodes on any specific one of the multi-stage inverter rings to a counterpart one of the nodes on another one of the multi-stage inverter rings so as to join the specific and other multi-stage inverter rings to each other in order to shift the phases of generated oscillation signals from each other by a fixed difference: and a current source connected to the inverters of the multi-stage inverter rings and the inverters of the inverter group.

### CROSS REFERENCES TO RELATED APPLICATIONS

The present invention contains subject matter related to Japanese Patent Application JP 2007-036425 filed in the Japan Patent Office on Feb. 16, 2007, the entire contents of which being incorporated herein by reference.

### BACKGROUND OF THE INVENTION

1. Field of the Invention

The present invention relates to an oscillation circuit (or an oscillator) for generating an oscillation signal by making use of inverters (or inversion circuits) connected in cascade to form a ring. More particularly, the present invention relates to an oscillation circuit, the oscillation frequency (or the resonant frequency) of which can be controlled.

2. Description of the Related Art

A PLL (Phase-Locked Loop) circuit is used in a wide range of applications such as generation of an oscillation signal having a high spectrum precision and generation of a clock signal having a frequency and a phase, which are locked to a data signal. Typical applications of the PLL circuit are the radio communication making use of hand phones as main communication means, a serial communication through a variety of cables and a reproduction system (or a read channel) for reproducing recorded digital data from a disk recording medium.

First of all, a PLL circuit is necessary to display a performance to output a signal having high precision. Since the precision of a signal output by a PLL circuit deteriorates due to hot noises and noises inherent in devices employed in the PLL circuit, it is desirable to suppress the noises. As indicators used for evaluating the precision of a signal output by a PLL circuit, in general, a jitter performance and a phase noise are used in a wide range of PLL circuits.

A PLL circuit includes a VCO (Voltage-Controlled Oscillator). In most PLL circuits, the VCO employed therein serves as a main source undesirably generating jitters and phase noises. As a method for improving the jitter performance of a VCO employed in a PLL circuit by adjustment of the band of the PLL circuit, there is a technique for reducing noises by correction. By the way, the effort to improve the jitter performance of a VCO is an effort to decrease the magnitude of the noises themselves.

There are two configurations of a VCO that can be integrated in a chip. One of the configurations is an LCVCO configuration employing an inductor and a capacitor. The other configuration is a ring-VCO configuration.

In general, the jitter performance of an LCVCO is good in comparison with a ring VCO.

On the other hand, a ring VCO offers a merit of having a wide variable frequency range, being capable of outputting a plurality of signals with phases different from each other and a merit of no need of inductor to mention a few. For this reason, in an application not imposing an absolutely strict need of a good jitter performance, a ring VCO is used in many cases. Since a ring VCO does not need an inductor in particular, the ring VCO not only substantially reduces demerits of effects of a needless electromagnetic field generated by the inductor as bad effects on other circuits, but also considerably reduces the size of an area occupied by the ring VCO. That is to say, the ring VCO brings about a merit of having no bad effects on other circuits and a merit of entailing only a small size of an area occupied thereby thus reducing the cost.

Because of the reasons described above, it is much desirable to improve the jitter and phase-noise performances of the ring VCO.

FIG. 1 is a diagram showing a typical configuration of an ordinary ring VCO.

In general, a ring VCO includes a plurality of identical VCO cells CL connected to each other to form a ring.

The oscillation frequency fo of a ring VCO is expressed in terms of the delay time Td of each VCO cell CL and a stage count N representing the number of stages, at each of which a VCO cell CL is provided, in accordance with the following equation.

fo=1/(2*N*Td) (1)

In addition, a signal output by any specific VCO cell CL has a phase shifted from the phase of a signal output by a VCO cell CL adjacent to the specific VCO cell CL by a phase difference of 2π/N [rad].

Ring VCOs can be classified into two big categories, i.e., ring VCOs of a differential type and ring VCOs of a single-end type.

FIG. 2 is a diagram showing a typical configuration of a cell CL1 employed in an ordinary single-end type ring VCO.

The VCO cell CL1 shown in FIG. 2 has a CMOS structure including an n-type MOS transistor NT1 and a p-type MOS transistor PT1, which are connected to each other to form a series circuit, which also includes variable loads LD1 and LD2 on the ground side and the power-supply side respectively. In FIG. 2, notations ND1 and ND2 each denote a middle node.

The CMOS structure shown in FIG. 2 can be replaced with a one-stage amplifier employing only transistors on either one of the two sides. In addition, one of the variable loads LD1 and LD2 can be eliminated. If a cell-stage count N representing the number of cells employed in a single-end type ring VCO is even, the VCO is stable (or latched) from the DC point of view when the VCO enters a state of in which signals output by two adjacent cells are set at high and low levels. Thus, in order to operate a single-end type VCO as an oscillation circuit, it is necessary to set the cell-stage count N at an odd number.

FIG. 3 is a diagram showing a typical configuration of a cell CL2 employed in an ordinary differential type ring VCO.

The VCO cell CL2 shown in FIG. 3 employs n-type MOS transistors NT2 and NT3, a current source I1 as well as loads LD3 and LD4. The sources of the n-type MOS transistors NT2 and NT3 are connected to each other at a tail node ND3. Connected between the tail node ND3 and the ground GND, the current source I1 is sustaining a current flowing from the sources of the n-type MOS transistors NT2 and NT3 at a constant magnitude. The load LD3 is connected between a voltage power supply VDD and the source of the NT2 whereas the load LD4 is connected between the voltage power supply VDD and the source of the NT3. A differential input signal is supplied between the gates of the n-type MOS transistors NT2 and NT3.

By the way, results of research carried out in recent years clearly indicate that, (with the same consumed current), the single-end type ring VCO generally displays a good jitter performance and a good phase-noise performance in comparison with the differential type ring VCO. For more information on the performances, the reader is suggested to refer to “Jitter and Phase Noise in Ring Oscillators,” IEEE Journal of Solid—State Circuits, the USA, June 1999, vol. 34, pp. 790-804 (hereinafter referred to as a Non-Patent Document 1) and “Oscillator Phase Noise: A Tutorial,” IEEE Journal of Solid—State Circuits, the USA, March 2003, vol. 35, pp. 326-336 (hereinafter referred to as a Non-Patent Document 2).

However, the single-end type ring VCO has some shortcomings described as follows.

The first shortcoming is a high sensitivity to variations of a voltage generated by the power supply. When the voltage of the power supply changes or the voltage of the power supply includes noises, the characteristic of the single-end type ring VCO substantially varies, considerably deteriorating the jitter performance and the phase-noise performance.

The second shortcoming is the inability to output a differential signal without providing special means for outputting a differential signal. A single-end signal output by the single-end type ring VCO is prone to be affected by effects of noises generated by circuits each embedded in the same chip as the single-end type ring VCO and very likely applies noises to the circuits at the same time. Thus, there is a large number of systems that each need a differential signal.

On the other hand, the differential type ring VCO does not have the shortcomings described above even though the differential type ring VCO generally displays a poor jitter performance and a poor phase-noise performance in comparison with the single-end type ring VCO for reasons described as follows.

In the first place, the differential type ring VCO has a small oscillation amplitude. This is because the existence of the current source limits the oscillation voltage to a small amplitude.

In the second place, while the single-end type ring VCO has a symmetrical structure constructed between the power-supply line and the ground line, the differential type ring VCO generally loses such a symmetrical structure. Thus, the differential type ring VCO has a lack of symmetry between the rising and falling portions of the waveform of the oscillation signal, displaying a poor jitter performance and a poor phase-noise performance in comparison with the single-end type ring VCO. It is also known that the lack of symmetry between the rising and falling portions of the waveform of the oscillation signal has a bad effect, that is, an effect of generating flicker noises.

In the third place, a voltage appearing at the tail node ND3 in the structure of the differential type ring VCO oscillates at a frequency twice the oscillation frequency. The oscillation of the voltage appearing at the tail node ND3 distorts the waveform of the oscillation signal, causing the differential type ring VCO to further lose the symmetry and generate an oscillation having a reduced amplitude. As a result, the differential type ring VCO generally displays a poor jitter performance and a poor phase-noise performance in comparison with the single-end type ring VCO.

As described above, the single-end type ring VCO has both merits and demerits different from merits and demerits of the differential type ring VCO. Various kinds of research have been carried out so far in order to implement a configuration offering the merits of both the single-end type ring VCO and the differential type ring VCO. For more information, the reader is suggested to refer to “A Three-Stage Coupled Ring Oscillator with Quadrature Outputs,” IEEE ISCAS. 2001, the USA, March 2001, vol. 1, pp. 6-9 (hereinafter referred to as a Non-Patent Document 3) and “A Coupled Two-Stage Ring Oscillator,” IEEE MWSCAS. 2001, the USA, August 2001, vol. 2, pp. 878-881 (hereinafter referred to as a Non-Patent Document 4).

### SUMMARY OF THE INVENTION

Non-patent references 3 and 4 propose a ring VCO having a configuration including two single-end rings joined to each other as shown in a diagram on the right-hand side of FIG. 4. Since the two single-end rings are joined to each other, a difference in phase is generated also between the two rings. As a result, an orthogonal signal is generated in the ring VCO a whole. A diagram on the left-hand side of FIG. 4 shows the basic VCO cell of the ring VCO.

Since this technology is the technology of the single-end type ring VCO, the proposed ring VCO raises a problem that the sensitivity to variations in power-supply voltage is as high as the single-end type ring VCO in the past. In addition, the proposed ring VCO also raises another problem that the proposed ring VCO does not have a symmetrical structure constructed between the power-supply line and the ground line so that the proposed ring VCO does not have a good jitter performance and a good phase-noise performance.

The present invention provides an oscillation circuit capable of generating distributed oscillation signals that have a low sensitivity to variations in power-supply voltage, an oscillation frequency variable over a wide range, a good jitter performance, a good phase-noise performance and a plurality of phases shifted from each other by a fixed difference.

In accordance with a first embodiment of the present invention, there is provided an oscillation circuit including: a plurality of multi-stage inverter rings (also each referred to as a main loop) each having an odd number of inverters connected to each other in cascade to form a ring through the same odd number of nodes on the ring; an inverter group (also referred to as a sub-loop) for connecting each one of the nodes on any specific one of the multi-stage inverter rings to a counterpart one of the nodes on another one of the multi-stage inverter rings so as to join the specific and other multi-stage inverter rings to each other in order to shift the phases of generated oscillation signals from each other by a fixed difference: and a current source connected to the inverters of the multi-stage inverter rings and the inverters of the inverter group.

In accordance with a second embodiment of the present invention, there is provided an oscillation circuit including: an even number of three-stage inverter rings each having three inverters connected to each other in cascade to form a ring through three nodes on the ring; an inverter group for connecting each one of the nodes on any specific one of the three-stage inverter rings to a counterpart one of the nodes on another one of the three-stage inverter rings so as to join the specific and other three-stage inverter rings to each other in order to shift the phases of generated oscillation signals from each other by a fixed difference: and a current source connected to the inverters of the three-stage inverter rings and the inverters of the inverter group.

It is desirable to design the oscillation circuit into a configuration in which the inverter group includes a plurality of inverter pairs each having: an inverter for connecting one of the nodes on any specific one of the multi-stage inverter rings to a counterpart one of the nodes on another one of the multi-stage inverter rings in a direction from the specific multi-stage inverter ring to the other multi-stage inverter ring; and another inverter for connecting one of the nodes on any specific one of the multi-stage inverter rings to a counterpart one of the nodes on another one of the multi-stage inverter rings in a direction from the other multi-stage inverter ring to the specific multi-stage inverter ring.

It is desirable to design the oscillation circuit into a configuration in which: the current source has a common node connected to a power-supply input terminal of each of the inverters as a node common to the inverters; and the current source has a function for sustaining the total of power-supply currents each supplied to one of the inverters at a constant value.

It is desirable to design the oscillation circuit into a configuration in which the current source changes the total of power-supply currents in accordance with a control signal supplied to the current source.

It is desirable to design the oscillation circuit into a configuration in which: each of the inverters has a first transistor of a first conduction type and a second transistor of a second conduction type; the first transistor and the second transistor are connected to each other in series to form a series circuit; and one end of the series circuit is connected to the common node.

It is desirable to design the oscillation circuit into a configuration in which: the number of aforementioned three-stage inverter rings is two and the number of aforementioned inverter pairs is three; the two three-stage inverter rings and the three inverter pairs form an oscillation core; and the oscillation core is capable of generating six oscillation signals distributed at fixed intervals in the phase space (or six oscillation signals with phases shifted from each other by a fixed difference of 60 degrees).

It is desirable to design the oscillation circuit into a configuration in which: the number of aforementioned three-stage inverter rings is two and the number of aforementioned inverter pairs is three; the two three-stage inverter rings and the three inverter pairs form an oscillation core; and the oscillation core is capable of generating three differential signals distributed at fixed intervals in the phase space (or three differential signals with phases shifted from each other by a fixed difference of 60 degrees).

In accordance with the present invention, the multi-stage inverter ring having an odd stage count representing the number of stages in each of the inverter rings becomes an oscillator having a very high speed. Thus, the oscillation circuit employing the multi-stage inverter ring is capable of oscillating at a high speed. Typically, the number of stages in each of the inverter rings is three.

In addition, the inverter pairs function as coupling inverters (or a coupling latch). Thus, the inverters composing an even number of such three-stage inverter rings are synchronized to each other instead of oscillating independently of each other. Typically, the even number of such three-stage inverter rings is two. As a result, the oscillation core is capable of generating three differential signals distributed at fixed intervals in the phase space (or three differential signals with phases shifted from each other by a fixed difference of 60 degrees).

In accordance with the present invention, it is possible to implement a high-speed ring oscillation circuit capable of generating distributed differential signals that have a low sensitivity to variations in power-supply voltage, an oscillation frequency variable over a wide range, a good jitter performance, a good phase-noise performance and a plurality of phases shifted from each other by a fixed difference and implement a PLL circuit employing the high-speed ring oscillation circuit.

### BRIEF DESCRIPTION OF THE DRAWINGS

These and other objects and features of the present invention will become clear from the following description of the preferred embodiments given with reference to the accompanying diagrams, in which:

FIG. 1 is a diagram showing a typical configuration of an ordinary ring VCO;

FIG. 2 is a diagram showing a typical configuration of a cell employed in an ordinary single-end type ring VCO;

FIG. 3 is a diagram showing a typical configuration of a cell employed in an ordinary differential type ring VCO;

FIG. 4 is a diagram showing a typical configuration of a ring VCO and a cell of the VCO;

FIG. 5 is a diagram showing a typical configuration of an oscillation core of an oscillation circuit according to a first embodiment of the present invention;

FIG. 6 is a diagram showing a typical configuration of each inverter (or each inversion circuit) employed in the oscillation circuit shown in FIG. 5;

FIG. 7A is a diagram showing a typical N-side current source for controlling a power-supply current flowing through the inverter shown in FIG. 6;

FIG. 7B is a diagram showing a typical P-side current source for controlling a power-supply current flowing through the inverter shown in FIG. 6;

FIG. 8A is a diagram deliberately showing the typical N-side current source shown in FIG. 7A in order to explain different ways of employing a current source in the oscillation circuit shown in FIG. 1;

FIG. 8B is a diagram showing an actual circuit of the N-side current source shown in FIG. 8A;

FIG. 8C is a diagram deliberately showing the typical P-side current source shown in FIG. 7B in order to explain different ways of employing a current source in the oscillation circuit shown in FIG. 1;

FIG. 8D is a diagram showing an actual circuit of the P-side current source shown in FIG. 8C;

FIG. 9 is a diagram showing the first embodiment implementing the oscillation core of the oscillation circuit shown in FIG. 5 with each inverter represented by an arrow;

FIG. 10A is a diagram showing a first three-stage of the oscillation core shown in FIG. 9;

FIG. 10B is a diagram showing a second three-stage of the oscillation core shown in FIG. 9;

FIG. 10C is a diagram showing inverters serving as a coupling latch in the oscillation core shown in FIG. 9;

FIG. 11A is a diagram showing a second embodiment implementing the oscillation core of an oscillation circuit including additional inverters each oriented in the same direction as that of inverters employed in the first and second three-stage inverter rings of the oscillation circuit according to the first embodiment; and

FIG. 11B is a diagram showing the second embodiment implementing the oscillation core of an oscillation circuit including additional inverters each oriented in a direction opposite to that of inverters employed in the first and second three-stage inverter rings of the oscillation circuit according to the first embodiment.

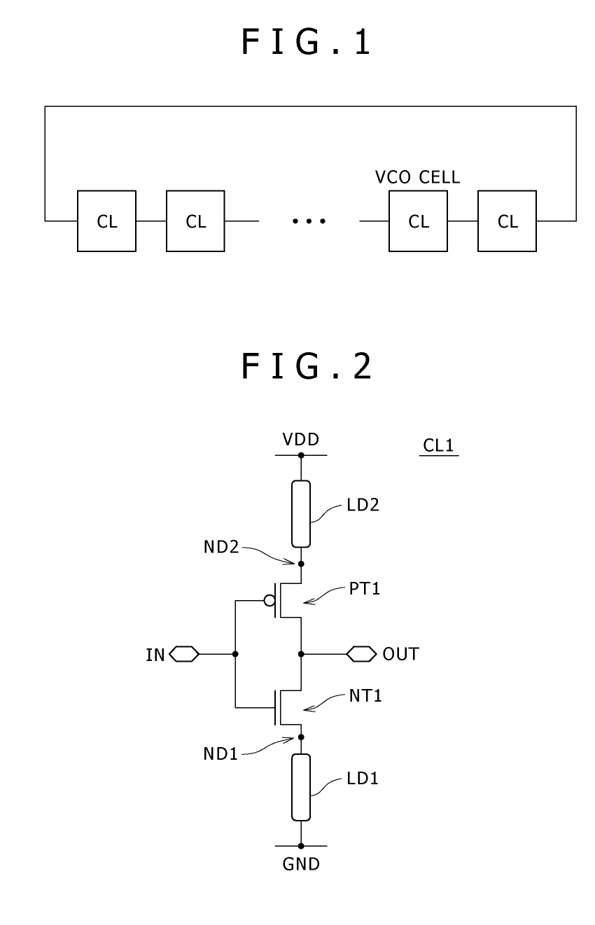

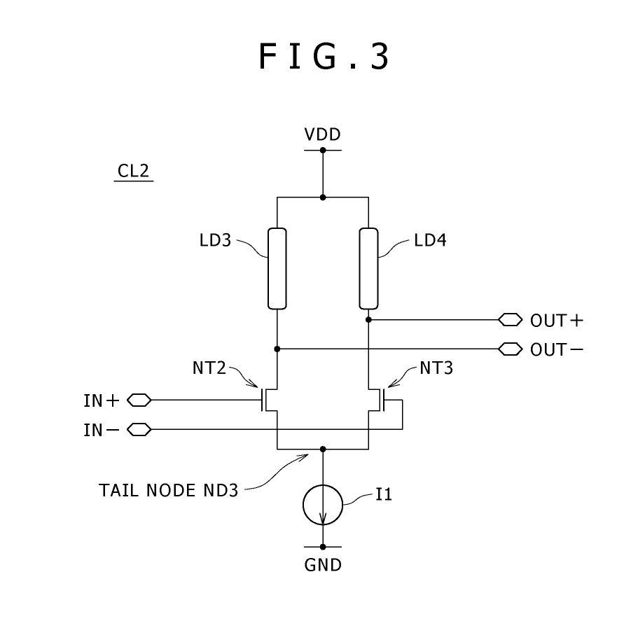

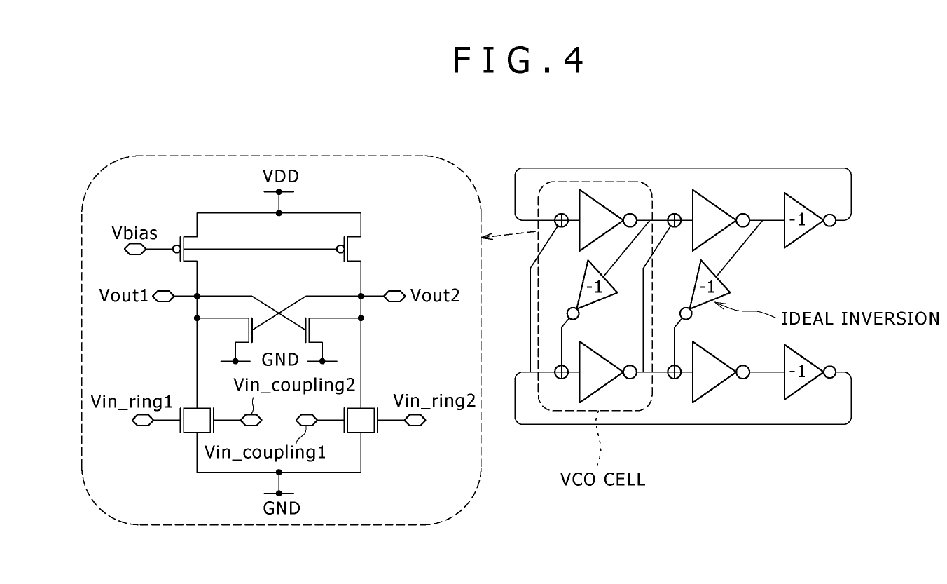

### DETAILED DESCRIPTION OF THE PREFERRED EMBODIMENTS

Preferred embodiments of the present invention are explained by referring to diagrams as follows.

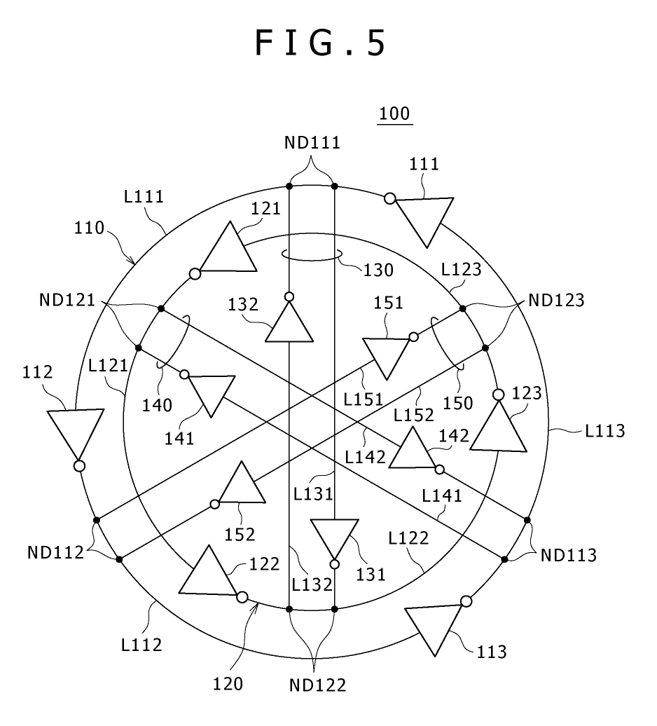

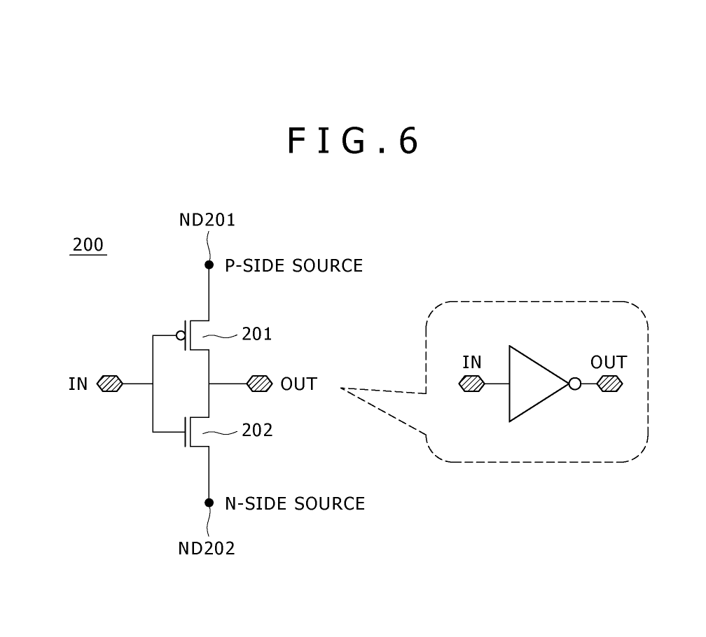

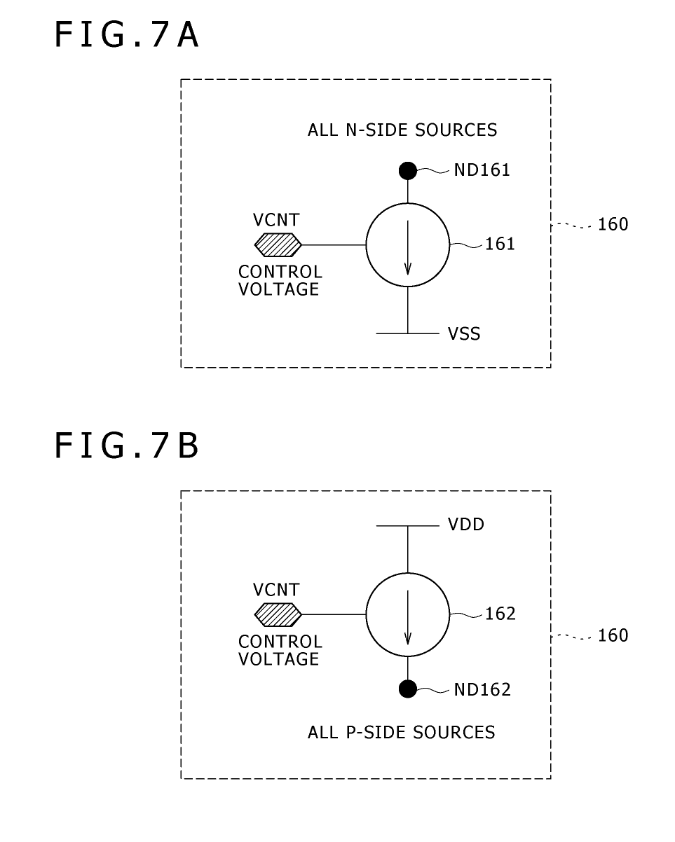

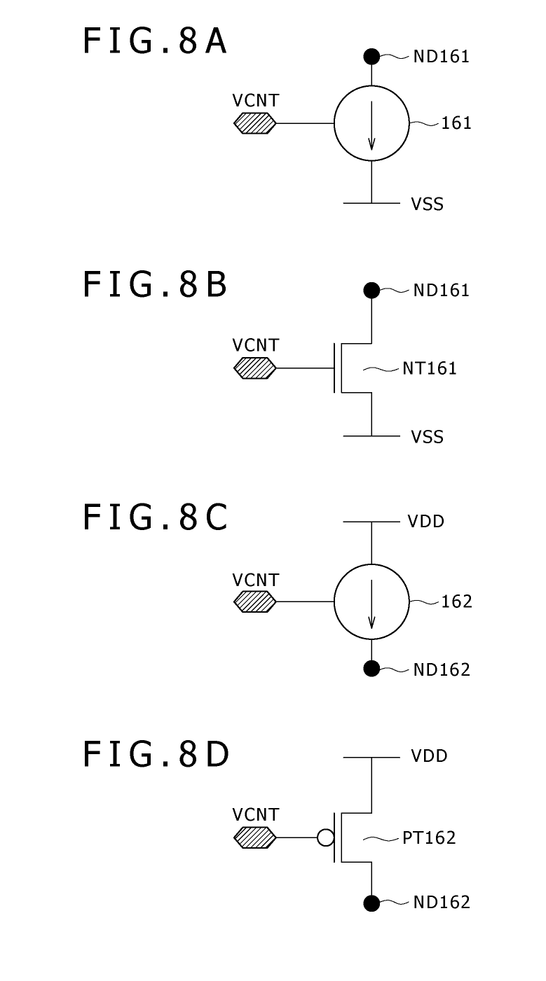

FIG. 5 is a diagram showing a typical configuration of an oscillation core of an oscillation circuit 100 according to an embodiment of the present invention. FIG. 6 is a diagram showing a typical configuration of an inverter (or an inversion circuit) employed in the oscillation circuit. FIGS. 7 and 8 are diagrams each showing a current-source circuit for controlling power-supply currents of the inverters.

Basically, the oscillation circuit 100 is designed as a ring VCO circuit having merits of both the single-end type ring VCO and the differential type ring VCO.

An oscillation core of the oscillation circuit 100 typically employs an even number of three-stage inverter rings each forming a main loop. In the typical configuration shown in FIG. 5, the oscillation circuit 100 includes first and second three-stage inverter rings 110 and 120. The three stages in the first three-stage inverter ring 110 are connected to each other through nodes ND111, ND112 and ND113. By the same token, the three stages in the second three-stage inverter ring 120 are connected to each other through nodes ND121, ND122 and ND123. The first and second three-stage inverter rings 110 and 120 are connected to each other by first, second and third inverter pairs 130, 140 and 150 each providing a fixed phase relation to generated oscillation signals. To put it concretely, the first inverter pair 130 connects the node ND111 to the node ND122, the second inverter pair 140 connects the node ND113 to the node ND121 whereas the third inverter pair 150 connects the node ND112 to the node ND123. The oscillation circuit 100 also employs a current source 160 not shown in the figure. The first three-stage inverter ring 110, the second three-stage inverter ring 120, the first inverter pair 130, the second inverter pair 140, the third inverter pair 150 and the current source 160 are each a main configuration element of the oscillation circuit 100. It is to be noted that, serving as a sub-loop, each of the first, second and third inverter pairs 130, 140 and 150 forms an inverter-pair group.

The main configuration elements of the oscillation circuit 100 are each described as follows.

The first three-stage inverter ring 110 has first, second and third inverters (or inversion circuits) 111, 112 and 113, which are connected to each other in cascade to form a ring referred to as the main loop cited above. The output terminal of the first inverter 111 is connected to the input terminal of the second inverter 112 by a line L111 serving as a connection path including the node ND111 between the input and output terminals.

By the same token, the output terminal of the second inverter 112 is connected to the input terminal of the third inverter 113 by a line L112 serving as a connection path including the node ND112 between the input and output terminals.

In the same way, the output terminal of the third inverter 113 is connected to the input terminal of the first inverter 111 by a line L113 serving as a connection path including the node ND113 between the input and output terminals.

Likewise, the second three-stage inverter ring 120 has first, second and third inverters (or inversion circuits) 121, 122 and 123, which are connected to each other in cascade to form a ring referred to as the main loop cited above.

The output terminal of the first inverter 121 is connected to the input terminal of the second inverter 122 by a line L121 serving as a connection path including the node ND121 between the input and output terminals.

By the same token, the output terminal of the second inverter 122 is connected to the input terminal of the third inverter 123 by a line L122 serving as a connection path including the node ND122 between the input and output terminals.

In the same way, the output terminal of the third inverter 123 is connected to the input terminal of the first inverter 121 by a line L123 serving as a connection path including the node ND123 between the input and output terminals.

The first inverter pair 130 has first and second inverters 131 and 132.

The input terminal of the first inverter 131 is connected to the node ND111 of the first three-stage inverter ring 110 whereas the output terminal of the inverter 131 is connected to the node ND122 of the second three-stage inverter ring 120. A line L131 is the connection path connecting the node ND111 to the node ND122 through the first inverter 131.

On the other hand, the output terminal of the second inverter 132 is connected to the node ND111 of the first three-stage inverter ring 110 whereas the input terminal of the inverter 131 is connected to the node ND122 of the second three-stage inverter ring 120. A line L132 is the connection path connecting the node ND111 to the node ND122 through the second inverter 132.

By the same token, the second inverter pair 140 has first and second inverters 141 and 142.

The input terminal of the first inverter 141 is connected to the node ND113 of the first three-stage inverter ring 110 whereas the output terminal of the inverter 141 is connected to the node ND121 of the second three-stage inverter ring 120. A line L141 is the connection path connecting the node ND113 to the node ND121 through the first inverter 141.

On the other hand, the output terminal of the second inverter 142 is connected to the node ND113 of the first three-stage inverter ring 110 whereas the input terminal of the inverter 141 is connected to the node ND121 of the second three-stage inverter ring 120. A line L142 is the connection path connecting the node ND113 to the node ND121 through the second inverter 142.

In the same way, the third inverter pair 150 has first and second inverters 151 and 152.

The input terminal of the first inverter 151 is connected to the node ND112 of the first three-stage inverter ring 110 whereas the output terminal of the inverter 151 is connected to the node ND123 of the second three-stage inverter ring 120. A line L151 is the connection path connecting the node ND112 to the node ND123 through the first inverter 151.

On the other hand, the output terminal of the second inverter 152 is connected to the node ND113 of the first three-stage inverter ring 110 whereas the input terminal of the inverter 151 is connected to the node ND123 of the second three-stage inverter ring 120. A line L152 is the connection path connecting the node ND112 to the node ND123 through the second inverter 152.

In this way, the first inverter pair 130, the second inverter pair 140 and the third inverter pair 150 connect the first three-stage inverter ring 110 to the second three-stage inverter ring 120 and function as coupling inverters (or a coupling latch) providing a fixed phase relation to generated oscillation signals.

Basic units of the oscillation circuit 100 are the inverters 111 to 113, 121 to 123, 131, 132, 141, 142, 151 and 152. The basic units are each implemented as a CMOS inverter 200 like one shown in FIG. 6.

As shown in the figure, the CMOS inverter 200 includes a p-type (first conduction type) MOS transistor 201 and an n-type (second conduction type) MOS transistor 202 connected between nodes ND201 and ND202 to form a series circuit.

The source of the p-type CMOS transistor 201 is connected to the node ND201, the drain of the p-type CMOS transistor 201 is connected to an output terminal OUT and the gate of the p-type CMOS transistor 201 is connected to an input terminal IN. On the other hand, the source of the n-type CMOS transistor 202 is connected to the node ND202, the drain of the n-type CMOS transistor 202 is connected to the output terminal OUT and the gate of the n-type CMOS transistor 202 is connected to the input terminal IN.

Thus, when the voltage supplied to the input terminal IN is set at a high level, the n-type CMOS transistor 202 is turned on but the p-type CMOS transistor 201 is turned off. As a result, the voltage appearing at the output terminal OUT is brought to a low level. When the voltage supplied to the input terminal IN is set at the low level, on the other hand, the n-type CMOS transistor 202 is turned off but the p-type CMOS transistor 201 is turned on. As a result, the voltage appearing at the output terminal OUT is raised to the high level.

The N-side source connected to the source of the n-type CMOS transistor 202 serves as a negative-side power-supply input terminal to be connected to a common node ND161 as shown in FIG. 7A. On the other hand, the P-side source connected to the source of the p-type CMOS transistor 201 serves as a positive-side power-supply input terminal to be connected to a common node ND162 as shown in FIG. 7B. As described above, the p-type CMOS transistor 201 and the n-type CMOS transistor 202 are transistors employed in each of the basic elements, which are the inverters 111 to 113, 121 to 123, 131, 132, 141, 142, 151 and 152.

As described above, the oscillation circuit 100 includes a current source 160. To put it concretely, the oscillation circuit 100 includes a current source 161 provided between the node ND202 and a reference electric potential (such as a ground electric potential) VSS as shown in FIG. 7A. As an alternative, the oscillation circuit 100 includes a current source 162 provided between the node ND201 and the supply line of a power-supply voltage VDD as shown in FIG. 7B.

The current source circuits 161 and/or 162 are connected to each of the inverters through the common nodes ND161 and/or ND162 respectively, sustaining the total of power-supply currents each fed to one of the inverters at a constant magnitude. The current source circuits 161 and/or 162 are capable of changing the total of power-supply currents in accordance with a control signal VCNT supplied to the current source circuits 161 and/or 162.

To be more specific, in accordance with the control signal VCNT, the current source circuits 161 and/or 162 change a current flowing from the node ND161 to the reference electric potential VSS as shown in FIG. 7A and/or a current flowing from the power-supply voltage VDD to the node ND162 as shown in FIG. 7B.

In order to make use of only the current source 161 shown in FIG. 7A, the absorption common node ND161 is short-circuited to the N-side source node ND202 included in each of the inverters of the oscillation core. In this case, the P-side source node ND201 included in each of the inverters of the oscillation core is short-circuited to the power-supply voltage VDD. As described above, the inverters of the oscillation core are the inverters 111 to 113, 121 to 123, 131, 132, 141, 142, 151 and 152.

In order to make use of only the current source 162 shown in FIG. 7B, on the other hand, the injection common node ND162 is short-circuited to the P-side source node ND201 included in each of the inverters of the oscillation core. In this case, the N-side source node ND202 included in each of the inverters of the oscillation core is short-circuited to the ground. As described above, the inverters of the oscillation core are the inverters 111 to 113, 121 to 123, 131, 132, 141, 142, 151 and 152.

In the oscillation circuit 100 according to the embodiment, the oscillation frequency of the oscillation circuit 100 is controlled by varying the currents generated by the current source 161 and/or the current source 162 in accordance with the control signal VCNT.

As shown in FIGS. 8A and 8B, the current source 161 can be implemented as an NMOS transistor NT161.

In this case, the drain of the NMOS transistor NT161 is connected to the node ND161, the source of the NMOS transistor NT161 is connected to the reference electric potential VSS whereas the gate of the NMOS transistor NT161 is connected to the supply line of the control signal VCNT.

By the same token, as shown in FIGS. 8C and 8D, the current source 162 can be implemented as a PMOS transistor NT162.

In this case, the drain of the PMOS transistor NT162 is connected to the node ND162, the source of the PMOS transistor NT162 is connected to the power-supply voltage VDD whereas the gate of the PMOS transistor NT162 is connected to the supply line of the control signal VCNT.

The following description explains the oscillation core included in the oscillation circuit 100 as a core employing the first three-stage inverter ring 110, the second three-stage inverter ring 120, the first inverter pair 130, the second inverter pair 140 and the third inverter pair 150 as shown in FIG. 5. However, the description does not explain the current source 160.

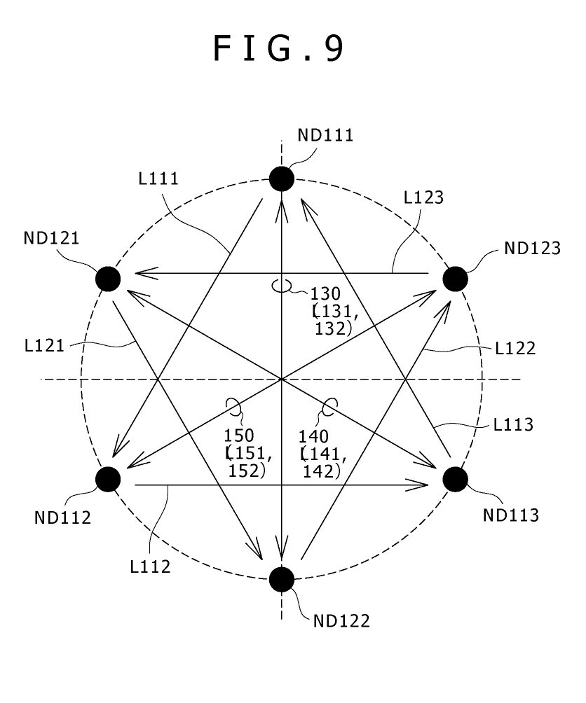

In order to make the explanation simple, each inverter employed in the oscillation circuit 100 is represented by an arrow as shown in FIG. 9.

FIG. 9 is a diagram showing a first embodiment implementing the oscillation circuit 100 shown in FIG. 5.

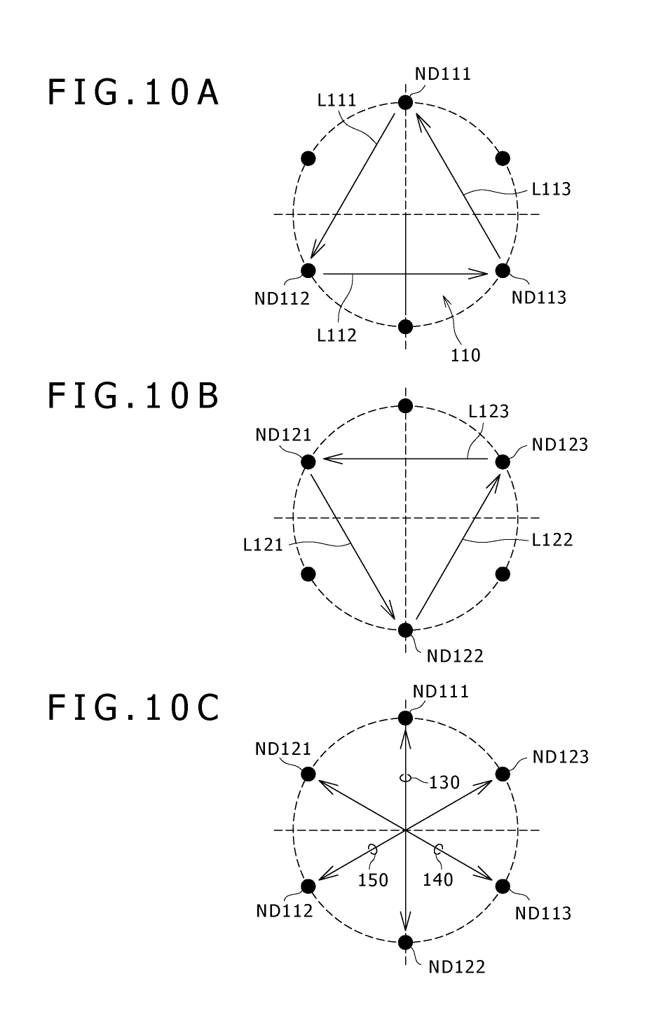

FIGS. 10A, 10B and 10C are diagrams showing elements obtained by decomposing the first embodiment shown in FIG. 9. To be more specific, FIGS. 10A and 10B show the first and second three-stage inverter rings 110 and 120 respectively whereas FIG. 10C shows a coupling latch (or the inverter pairs 130, 140 and 150).

In this embodiment, the first three-stage inverter ring 110 is seen as an equilateral triangle having the connection paths L111, L112 and L113 as its sides and the nodes ND111, ND112 and ND113 as its vertexes as shown in FIG. 10A. By the same token, the second three-stage inverter ring 120 is seen as an equilateral triangle having the connection paths L121, L122 and L123 as its sides and the nodes ND121, ND122 and ND123 as its vertexes as shown in FIG. 10B. If the nodes ND111, ND112, ND113, ND121, ND122 and ND123 are placed on the circumference of a circle, being separated from each other by the same rotation angle as shown in FIG. 9, every two nodes at the ends of a diagonal line passing through the center of the circle are connected to each other by the diagonal line, which is the first inverter pair 130, 140 or 150 as shown in FIG. 10C.

In this way, the first three-stage inverter ring 110 and the second three-stage inverter ring 120, which are originally not connected to each other, have relation links through an inverter-pair group including of the inverter pairs 130, 140 and 150.

FIG. 10 also shows a relation between phases of six signals appearing at at the nodes ND111, ND112, ND113, ND121, ND122 and ND123.

As described above, the nodes ND111, ND112, ND113, ND121, ND122 and ND123 are separated from each other along the circumference of a circle by a rotation angle of 60 degrees (=360 degrees/6). This rotation angle is a phase difference between the six signals generated by the oscillation circuit 100. The six signals can be regarded as three differential signals having phases separated from each other by 60 degrees.

Characteristics of the embodiment of the present invention are described as follows. As shown in FIGS. 5, 9 and 10, the oscillation circuit 100 provided by the present embodiment includes a plurality of three-stage inverter rings and coupling inverters (serving as a coupling latch) connecting the three-stage inverter rings to each other. To be more specific, the oscillation circuit 100 provided by the present invention includes two three-stage inverter rings and three inverter pairs (serving as a coupling latch) connecting the three-stage inverter rings to each other.

As generally known, the three-stage inverter rings function as a high-speed oscillator.

Thus, the oscillation circuit 100 according to the embodiment is capable of oscillating at a high speed.

In addition, by virtue of the coupling inverters (serving as a coupling latch) connecting the three-stage inverter rings to each other, the two three-stage inverter rings are synchronized to each other instead of oscillating independently of each other.

Thus, six phases shifted from each other by a fixed difference of 60 degrees as the phases of six oscillation signals generated by the oscillation circuit 100 are obtained. The oscillation signals generated by the oscillation circuit 100 with six phases shifted from each other by a fixed difference can be seen as three differential signals with phases different from each other.

In addition, the oscillation core has a configuration including inverters all laid out symmetrically between the power supply and the ground. Thus, the symmetry of the waveform of the oscillation signal as well as the phase noise performance and the jitter performance are also good as well. On top of that, since the oscillation core can be controlled by varying the voltage generated by a control power supply, the core is proof against variations in power-supply voltage and has a broad range of frequency changes.

As described above, in accordance with the embodiment, the oscillation core of the oscillation circuit 100 employs an even number of three-stage inverter rings each typically forming a main loop. In the typical configuration shown in FIG. 5, the oscillation circuit 100 includes first and second three-stage inverter rings 110 and 120. The three stages in the first three-stage inverter ring 110 are connected to each other through nodes ND111, ND112 and ND113. By the same token, the three stages in the second three-stage inverter ring 120 are connected to each other through nodes ND121, ND122 and ND123. The first and second three-stage inverter rings 110 and 120 are connected to each other by first, second and third inverter pairs 130, 140 and 150 providing a fixed phase relation to generated oscillation signals. To put it concretely, the first inverter pair 130 connects the node ND111 to the node ND122, the second inverter pair 140 connects the node ND113 to the node ND121 whereas the third inverter pair 150 connects the node ND112 to the node ND123. The oscillation circuit 100 also employs a current source 160 not shown in the figure. The first three-stage inverter ring 110, the second three-stage inverter ring 120, the first inverter pair 130, the second inverter pair 140, the third inverter pair 150 and the current source 160 are each a main configuration element of the oscillation circuit 100. Thus, it is possible to implement a high-speed ring oscillation circuit capable of generating distributed differential signals that have a low sensitivity to variations in power-supply voltage, an oscillation frequency variable over a wide range, a good jitter performance, a good phase-noise performance and a plurality of phases shifted from each other by a fixed difference of 60 degrees and implement a PLL circuit employing the high-speed ring oscillation circuit.

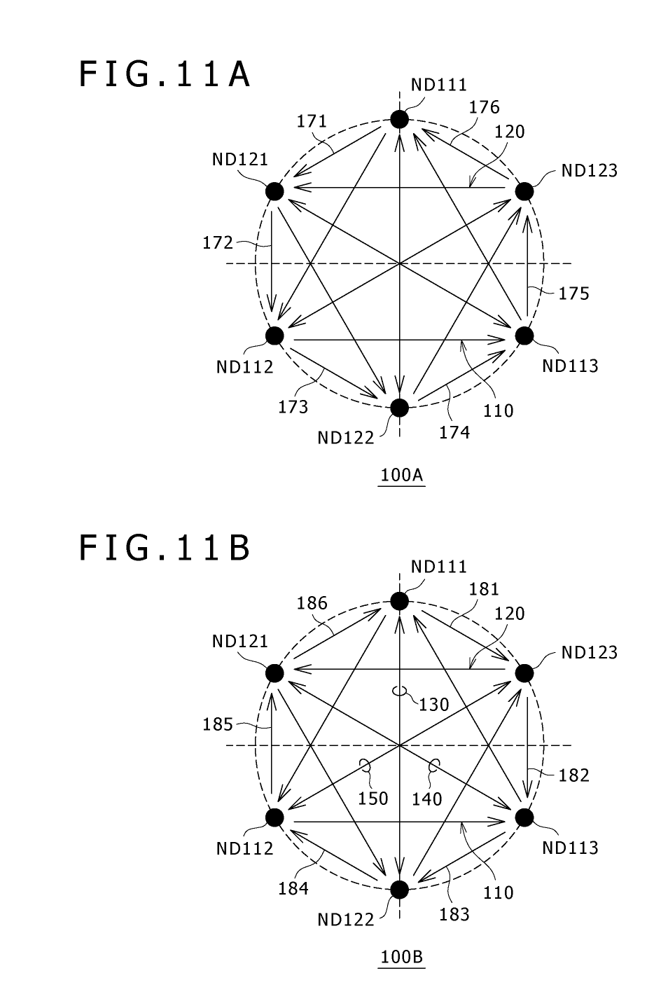

The configuration of first embodiment has been described so far by referring to FIGS. 9 and 10. A second embodiment is obtained by providing the first embodiment shown in FIG. 9 with additional inverters along the circumference of the circle as shown in FIGS. 11 (A) and (B).

FIGS. 11A and 11B are each a diagram showing the configuration of an oscillation core including two three-stage inverter rings in accordance with the second embodiment. The configurations shown in the figures are different from each other in that, in the case of the configuration shown in FIG. 11A, the direction of the additional inverters is the counterclockwise direction, which is the same direction as that of the inverters employed in the first and second three-stage inverter rings but, in the case of the configuration shown in FIG. 11B, the direction of the additional inverters is the clockwise direction, which is a direction opposite to that of the inverters employed in the first and second three-stage inverter rings.

To put it concretely, in the case of the typical configuration shown in FIG. 11A, an additional inverter 171 connects the node ND111 of the first three-stage inverter ring 110 to the node ND121 of the second three-stage inverter ring 120, being oriented in the direction from the node ND111 to the node ND121. By the same token, an additional inverter 172 connects the node ND121 of the second three-stage inverter ring 120 to the node ND112 of the first three-stage inverter ring 110, being oriented in the direction from the node ND121 to the node ND112. In the same way, an additional inverter 173 connects the node ND112 of the first three-stage inverter ring 110 to the node ND122 of the second three-stage inverter ring 120, being oriented in the direction from the node ND112 to the node ND122. Likewise, an additional inverter 174 connects the node ND122 of the second three-stage inverter ring 120 to the node ND113 of the first three-stage inverter ring 110, being oriented in the direction from the node ND122 to the node ND113. Similarly, an additional inverter 175 connects the node ND113 of the first three-stage inverter ring 110 to the node ND123 of the second three-stage inverter ring 120, being oriented in the direction from the node ND113 to the node ND123. Finally, an additional inverter 176 connects the node ND123 of the second three-stage inverter ring 120 to the node ND111 of the first three-stage inverter ring 110, being oriented in the direction from the node ND123 to the node ND111.

In the case of the typical configuration shown in FIG. 11B, on the other hand, an additional inverter 181 connects the node ND111 of the first three-stage inverter ring 110 to the node ND123 of the second three-stage inverter ring 120, being oriented in the direction from the node ND111 to the node ND123. By the same token, an additional inverter 182 connects the node ND123 of the second three-stage inverter ring 120 to the node ND113 of the first three-stage inverter ring 110, being oriented in the direction from the node ND123 to the node ND113. In the same way, an additional inverter 183 connects the node ND113 of the first three-stage inverter ring 110 to the node ND122 of the second three-stage inverter ring 120, being oriented in the direction from the node ND113 to the node ND122. Likewise, an additional inverter 184 connects the node ND122 of the second three-stage inverter ring 120 to the node ND112 of the first three-stage inverter ring 110, being oriented in the direction from the node ND122 to the node ND112. Similarly, an additional inverter 185 connects the node ND112 of the first three-stage inverter ring 110 to the node ND121 of the second three-stage inverter ring 120, being oriented in the direction from the node ND112 to the node ND121. Finally, an additional inverter 186 connects the node ND121 of the second three-stage inverter ring 120 to the node ND111 of the first three-stage inverter ring 110, being oriented in the direction from the node ND121 to the node ND111.

The second embodiment having the configurations described above is capable of giving the same effects as the effects provided by the first embodiment as described earlier.

In addition, it should be understood by those skilled in the art that a variety of modifications, combinations, sub-combinations and alterations may occur, depending on design requirements and other factors insofar as they are within the scope of the appended claims or the equivalents thereof.

What is claimed is:

1. An oscillation circuit comprising:
a plurality of multi-stage inverter rings each having an odd number of inverters connected to each other in cascade to form a ring through the same odd number of nodes on said ring;
an inverter group for connecting each one of said nodes on any specific one of said multi-stage inverter rings to a counterpart one of said nodes on another one of said multi-stage inverter rings so as to join said specific and other multi-stage inverter rings to each other in order to shift the phases of generated oscillation signals from each other by a fixed difference; and
a current source connected to said inverters of said multi-stage inverter rings and said inverters of said inverter group.

2. The oscillation circuit according to claim 1 wherein said inverter group includes a plurality of inverter pairs each having:
an inverter for connecting one of said nodes on any specific one of said multi-stage inverter rings to a counterpart one of said nodes on another one of said multi-stage inverter rings in a direction from said specific multi-stage inverter ring to said other multi-stage inverter ring; and
another inverter for connecting one of said nodes on any specific one of said multi-stage inverter rings to a counterpart one of said nodes on another one of said multi-stage inverter rings in a direction from said other multi-stage inverter ring to said specific multi-stage inverter ring.

3. The oscillation circuit according to claim 1 wherein:
said current source has a common node connected to a power-supply input terminal of each of said inverters as a node common to said inverters; and
said current source has a function for sustaining the total of power-supply currents each supplied to one of said inverters at a constant value.

4. The oscillation circuit according to claim 3 wherein said current source changes said total of power-supply currents in accordance with a control signal supplied to said current source.

5. The oscillation circuit according to claim 3 wherein:
each of said inverters has a first transistor of a first conduction type and a second transistor of a second conduction type;
said first transistor and said second transistor are connected to each other in series to form a series circuit; and
one end of said series circuit is connected to said common node.

6. An oscillation circuit comprising:
an even number of three-stage inverter rings each having three inverters connected to each other in cascade to form a ring through three nodes on said ring;
an inverter group for connecting each one of said nodes on any specific one of said three-stage inverter rings to a counterpart one of said nodes on another one of said three-stage inverter rings so as to join said specific and other three-stage inverter rings to each other in order to shift the phases of generated oscillation signals from each other by a fixed difference; and
a current source connected to said inverters of said three-stage inverter rings and said inverters of said inverter group.

7. The oscillation circuit according to claim 6 wherein said inverter group includes a plurality of inverter pairs each having:
an inverter for connecting one of said nodes on any specific one of said multi-stage inverter rings to a counterpart one of said nodes on another one of said multi-stage inverter rings in a direction from said specific multi-stage inverter ring to said other multi-stage inverter ring; and
another inverter for connecting one of said nodes on any specific one of said multi-stage inverter rings to a counterpart one of said nodes on another one of said multi-stage inverter rings in a direction from said other multi-stage inverter ring to said specific multi-stage inverter ring.

8. The oscillation circuit according to claim 6 wherein:
said current source has a common node connected to a power-supply input terminal of each of said inverters as a node common to said inverters; and
said current source has a function for sustaining the total of power-supply currents each supplied to one of said inverters at a constant value.

9. The oscillation circuit according to claim 8 wherein said current source changes said total of power-supply currents in accordance with a control signal supplied to said current source.

10. The oscillation circuit according to claim 8 wherein:
each of said inverters has a first transistor of a first conduction type and a second transistor of a second conduction type;
said first transistor and said second transistor are connected to each other in series to form a series circuit; and
one end of said series circuit is connected to said common node.

11. The oscillation circuit according to claim 7 wherein:
the number of said three-stage inverter rings is two and the number of said inverter pairs is three;
said two three-stage inverter rings and said three inverter pairs form an oscillation core; and
said oscillation core is capable of generating six oscillation signals distributed at fixed intervals in the phase space.

12. The oscillation circuit according to claim 7 wherein:
the number of said three-stage inverter rings is two and the number of said inverter pairs is three;
said two three-stage inverter rings and said three inverter pairs form an oscillation core; and
said oscillation core is capable of generating three differential signals distributed at fixed intervals in the phase space.
